(19) United States
(12) Patent Application Publication
(10) Pub. No.: US 2025/0223703 A1
(43) Pub. Date: Jul. 10, 2025

(54) SUBSTRATE PROCESSING APPARATUS, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventor: Toshiyuki KIKUCHI, Toyama-shi (JP)

(73) Assignee: KOKUSAI ELECTRIC CORPORATION, Tokyo (JP)

(21) Appl. No.: 18/989,224

(22) Filed: Dec. 20, 2024

(30) Foreign Application Priority Data
Jan. 5, 2024 (JP) 2024-000739

(51) Int. Cl. C23C 16/52; C23C 16/44; C23C 16/458; H01L 21/66

(52) U.S. Cl. CPC C23C 16/52; C23C 16/4405; C23C 16/4583; H01L 22/12

(57) ABSTRACT

A technique includes a substrate processing apparatus comprising: a processing container that processes a substrate; a gas supplier for supplying a processing gas depositing a deposit, and a cleaning gas removing the deposit into the processing chamber, a controller, wherein the controller is configured to control the gas supplier so as to perform, a predetermined times, processing including: (a) forming the deposit on the substrate and the inner side of the processing container; and (b) removing the deposit on the inner side of the processing container. The controller is configured to calculate a difference between a lifetime cumulative film thickness value, which is a cumulative value of a thickness of the deposit in (a), and a cumulative etching amount, which is an amount of a thickness of the deposit estimated to be removed in (b), and obtaining a replacement time of the processing container on the basis of the difference.

### CROSS-REFERENCE TO RELATED APPLICATION

This application is based upon and claims the benefit of priority from Japanese Patent Application No. 2024-000739, filed on Jan. 5, 2024, the entire contents of which are incorporated herein by reference.

### FIELD

The present disclosure relates to a substrate processing apparatus, a method of manufacturing a semiconductor device, and a recording medium.

### DESCRIPTION OF THE RELATED ART

As a substrate processing apparatus that processes a substrate, there is known a substrate processing apparatus that includes a processing container and a support that supports the substrate in multiple stages, and performs film formation processing of the substrate in a state where the support is inserted into the processing container. In such a substrate processing apparatus, when the film formation processing of the substrate is repeatedly performed, a film may be accumulated in the processing container or the support. In this case, cleaning to remove the accumulated film is performed on both the processing container and the support.

### SUMMARY

In recent years, a substrate processing apparatus has been developed which improves throughput by preparing a plurality of supports for one processing container and transferring a substrate to another support while the substrate supported by a certain support is processed in the processing container. As described above, when a plurality of supports are operated for one processing container, there is a case where the plurality of supports are continuously cleaned. In this case, since the processing container is cleaned for each support, there is a concern that the processing container is over-etched. The replacement time of the processing container is accelerated by repeating the over-etching, but the replacement time of the processing container is often determined by the number of times of performing cleaning processing, and there is room for improvement.

The present disclosure provides a technology capable of accurately grasping a replacement time of a processing container.

According to one aspect of the present disclosure, there is provided a substrate processing apparatus, including: a processing container that processes a substrate; a gas supplier configured to supply a processing gas depositing a deposit, and a cleaning gas removing the deposit into the processing chamber; and a controller, wherein the controller is configured to control the gas supplier so as to perform, a predetermined times, processing including: (a) forming the deposit on the substrate and the inner side of the processing container; and (b) removing the deposit on the inner side of the processing container, and the controller is configured to be capable of calculating a difference between a lifetime cumulative film thickness value, which is a cumulative value of a thickness of the deposit adhering to the inner side of the processing container in (a), and a cumulative etching amount, which is an amount of a thickness of the deposit estimated to be removed in (b), and obtaining a replacement time of the processing container on the basis of the difference.

### BRIEF DESCRIPTION OF THE DRAWINGS

FIG. 1 is a transverse cross-sectional view illustrating a schematic configuration example of a substrate processing apparatus according to one embodiment of the present disclosure.

FIG. 2 is a longitudinal cross-sectional view illustrating a configuration example of the substrate processing apparatus according to one embodiment of the present disclosure.

FIG. 3 is a drawing illustrating an example of a configuration of a controller of the substrate processing apparatus according to one embodiment of the present disclosure.

FIG. 4A is a drawing for illustrating processing container information in the substrate processing apparatus according to one embodiment of this present disclosure.

FIG. 4B is a drawing for illustrating support information in the substrate processing apparatus according to one embodiment of this present disclosure.

FIG. 5 is an explanatory drawing for explaining an operation of the substrate processing apparatus according to one embodiment of the present disclosure.

FIG. 6 is a flowchart illustrating a substrate processing step of the substrate processing apparatus according to one embodiment of the present disclosure.

FIG. 7 is a flowchart of cleaning time determination processing of a support of the substrate processing apparatus according to one embodiment of the present disclosure.

FIG. 8 is a flowchart of replacement time determination processing of a processing container of the substrate processing apparatus according to one embodiment of the present disclosure.

FIG. 9 is a flowchart of replacement time determination processing of the support of the substrate processing apparatus according to one embodiment of the present disclosure.

FIG. 10 is an example of a display screen indicating states of the processing container and the support of the substrate processing apparatus according to one embodiment of the present disclosure.

### DETAILED DESCRIPTION

Hereinafter, an embodiment of the present disclosure will be described with reference to the drawings.

Note that the drawings used in the following description are all schematic and thus, for example, the dimensional relationship between each constituent element, the ratio between each constituent element, and the like in the drawings do not necessarily coincide with realities. In addition, the dimensional relationship between each constituent element, the ratio between each constituent element, and the like do not necessarily coincide among a plurality of drawings.

### (1) Configuration of Substrate Processing Apparatus

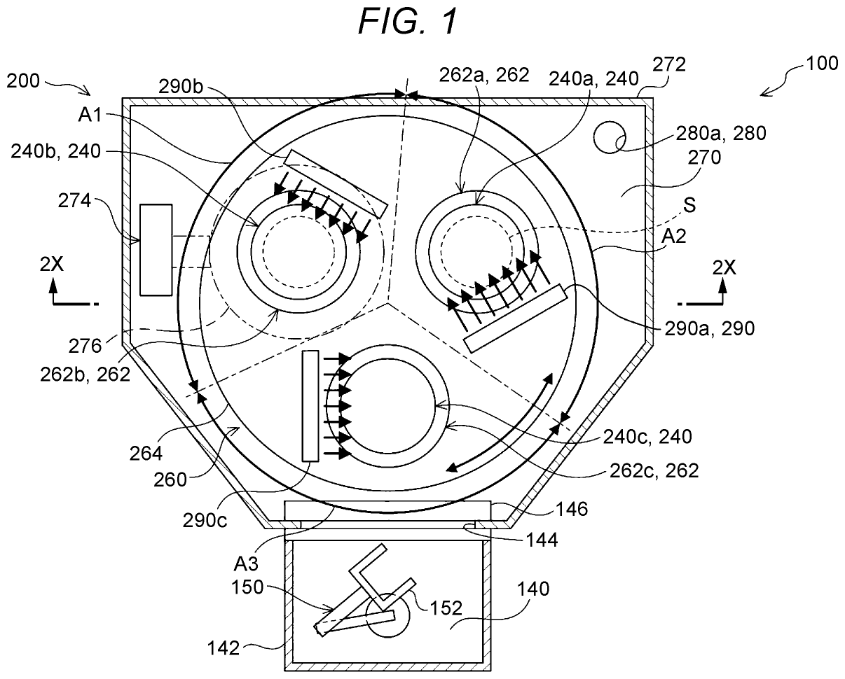

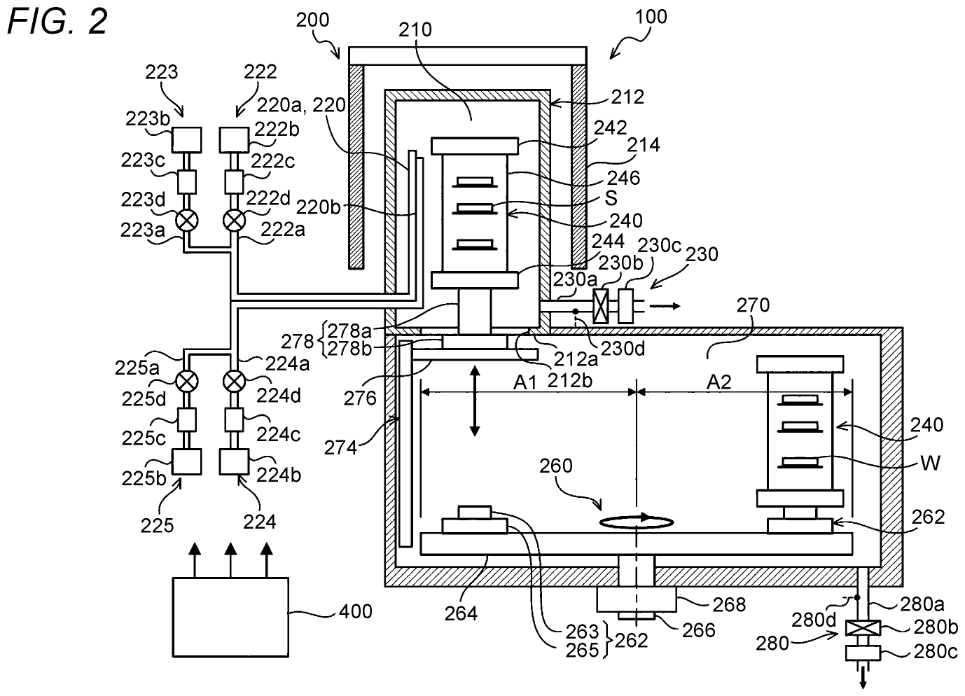

An outline configuration of a substrate processing apparatus according to one embodiment of the present disclosure will be described with reference to FIGS. 1 and 2. FIG. 1 is a transverse cross-sectional view illustrating a schematic configuration example of a substrate processing apparatus according to the present technology. FIG. 2 is a longitudinal cross-sectional view illustrating a schematic configuration example of the substrate processing apparatus according to one embodiment of the present disclosure, and is also a cross-sectional view taken along arrow 2X-2X in FIG. 1.

FIGS. 1 and 2 illustrate a substrate processing apparatus 100 to which the technology of the present disclosure is applied. The substrate processing apparatus 100 is an apparatus that processes a substrate S. The substrate processing apparatus 100 includes a transfer chamber 140, a reactor 200, a transfer chamber 270, and a controller 400.

### Transfer Chamber 140

The transfer chamber 140 is a chamber for transferring the substrate S. The transfer chamber 140 is configured by a housing 142.

The transfer chamber 140 is configured to communicate with the transfer chamber 270. Specifically, the transfer chamber 140 communicates with the transfer chamber 270 through a load-in and load-out port 144 provided in a housing 272 configuring the transfer chamber 270. The load-in and load-out port 144 is used as a passage for loading the substrate S from the transfer chamber 140 into the transfer chamber 270 and loading the substrate S from the transfer chamber 270 into the transfer chamber 140. The load-in and load-out port 144 is opened and closed by a gate valve 146 attached to the housing 272.

A transfer robot 150 that transfers the substrate S is installed in the transfer chamber 140. The transfer robot 150 has an arm 152 provided with an end effector. The transfer robot 150 is configured to be capable of ascending, descending, and rotating while maintaining airtightness of the transfer chamber 140 by an elevator (not illustrated) and a rotator (not illustrated).

The transfer robot 150 receives the substrate S before being processed by the reactor 200 from a device outside the transfer chamber 140, and loads the received substrate S into the transfer chamber 270. Further, the transfer robot 150 loads out the substrate S after being processed by the reactor 200 from the transfer chamber 270, and transfers the loaded-out substrate S to the device outside the transfer chamber 140. In the present embodiment, the substrate S before being processed by the reactor 200 is referred to as an unprocessed substrate S.

### Reactor 200

The reactor 200 is a chamber capable of processing the substrate S. The reactor 200 is, for example, a chamber for performing processing such as forming a thin film on the surface of the substrate S.

The reactor 200 includes a processing chamber 210. The processing chamber 210 is positioned on the upper side from the transfer chamber 270. The upper side as used herein indicates an upper side in a vertical direction. Further, in the case of a lower side indicates a lower side in the vertical direction. The vertical direction in the present embodiment is the same direction as the up and down direction of the substrate processing apparatus 100. Hereinafter, the upper side and the lower side in the vertical direction are simply referred to as the “upper side” and the “lower side” in an abbreviated manner.

The processing chamber 210 is a chamber capable of performing substrate processing including processing of heating the substrate S. The processing chamber 210 is mainly configured by a reaction tube 212 serving as an example of a processing container. In addition, a plurality of boats 240 are individually transferred to the processing chamber 210 to perform the substrate processing. In other words, the processing chamber 210 performs the substrate processing while replacing the plurality of boats 240.

On the outer peripheral side of the reaction tube 212, a heater 214 serving as a heater that heats the boat 240 and the substrate S supported by the boat 240 through the reaction tube 212 is disposed. The heater 214 is separated from the outer peripheral wall of the reaction tube 212. In the present embodiment, a resistance heater is used as the heater 214. As the heater 214, a heater other than the resistance heater may be used as long as the boat 240 and the substrate S supported by the boat 240 can be heated.

The upper end of the reaction tube 212 is closed. A flange portion 212a protruding radially inward of the reaction tube 212 is provided at the lower end of the reaction tube 212. The center of the flange portion 212a is opened to form a furnace opening 212b. The boat 240 is moved between the processing chamber 210 and the transfer chamber 270 through the furnace opening 212b.

The reaction tube 212 is configured to be capable of containing the boat 240 that supports the substrate S. In the internal space of the reaction tube 212, a region in which the boat 240 that supports the substrate S is stored is referred to as a processing region, and a section configuring the processing region is referred to as the processing chamber 210.

The reaction tube 212 has a plurality of nozzles 220 provided therein. Such nozzles 220 pass through the peripheral wall of the reaction tube 212 and extend to the upper side from the lower side. Each of the nozzles 220 is provided with a plurality of gas holes (not illustrated) at intervals in an extending direction. Gas supplied from the gas hole of the nozzle 220 is supplied to the substrate S supported by the boat 240 in the processing chamber 210.

The nozzle 220 is provided for each type of gas, for example. In the present embodiment, two nozzles 220a and 220b are used as an example. The nozzles 220 are disposed so as not to overlap each other in a horizontal direction.

As illustrated in FIG. 2, first gas is supplied from a first gas supplier 222 to the nozzle 220a. That is, the first gas supplier 222 is configured to supply the first gas to the nozzle 220a. The first gas supplier 222 includes a gas supply pipe 222a, a mass flow controller (MFC) 222c which is a flow rate controller, and a valve 222d which is an on-off valve. The gas supply pipe 222a includes a first gas source 222b, the MFC 222c, and the valve 222d in this order from an upstream direction. The gas supply pipe 222a is configured to communicate with the nozzle 220a. The first gas supplier 222 may include the first gas source 222b.

The first gas source 222b is a first gas (also referred to as “first element-containing gas”.) source containing a first element.

As illustrated in FIG. 2, cleaning gas is supplied to the nozzle 220a from a first cleaning gas supplier 223. That is, the first cleaning gas supplier 223 is configured to supply the cleaning gas to the nozzle 220a. The first cleaning gas supplier 223 includes a gas supply pipe 223a, an MFC 223c, and a valve 223d. The gas supply pipe 223a includes a first cleaning gas source 223b, the MFC 223c, and the valve 223d in this order from the upstream direction. The gas supply pipe 223a is connected to a portion of the gas supply pipe 222a on the downstream side from the valve 222d. The gas supply pipe 223a is configured to communicate with the nozzle 220a through the gas supply pipe 222a. The first cleaning gas source 223b may be included in the first cleaning gas supplier 223.

The first cleaning gas source 223b is a cleaning gas source.

As illustrated in FIG. 2, second gas is supplied to the nozzle 220b from the second gas supplier 224. That is, the second gas supplier 224 is configured to supply the second gas to the nozzle 220b. The second gas supplier 224 includes a gas supply pipe 224a, an MFC 224c, and a valve 224d. The gas supply pipe 224a includes a second gas source 224b, the MFC 224c, and the valve 224d in this order from the upstream direction. The gas supply pipe 224a is configured to communicate with the nozzle 220b. The second gas source 224b may be included in the second gas supplier.

The second gas source 224b is a second gas (hereinafter, also referred to as “second element-containing gas”.) source containing a second element. The second element-containing gas is one of the processing gas. The second element-containing gas may be considered as reactant gas or a modifying gas.

As illustrated in FIG. 2, the cleaning gas is supplied to the nozzle 220b from a second cleaning gas supplier 225. That is, the second cleaning gas supplier 225 is configured to supply the cleaning gas to the nozzle 220b. The second cleaning gas supplier 225 includes a gas supply pipe 225a, an MFC 225c, and a valve 225d. The gas supply pipe 225a includes a second cleaning gas source 225b, the MFC 225c, and the valve 225d in this order from the upstream direction. The gas supply pipe 225a is connected to a portion of the gas supply pipe 224a on the downstream side from the valve 224d. The gas supply pipe 225a is configured to communicate with the nozzle 220b through the gas supply pipe 224a. The second cleaning gas supplier 225 may include the second cleaning gas source 225b.

The second cleaning gas source 225b is a cleaning gas source containing fluorine. The second cleaning gas source 225b of the present embodiment is cleaning gas having the same properties as the first cleaning gas source 223b.

In the present embodiment, the number of the nozzles 220 is 2, but the present disclosure is not limited to this configuration. The number of the nozzles 220 may be set to 3 or more in accordance with the contents of the substrate processing. For example, a dedicated nozzle for supplying the cleaning gas may be provided, or a dedicated nozzle for supplying inert gas may be provided.

As shown in FIG. 2, an exhauster 230 is connected to the reaction tube 212. The exhauster 230 performs vacuum-exhaust so that the pressure in the reaction tube 212 is a predetermined pressure (the degree of vacuum). The exhauster 230 includes an exhaust pipe 230a, a valve 230b, and an auto pressure controller (APC) valve 230c serving as a pressure regulator. The exhauster 230 may include a vacuum pump (not illustrated) connected to the downstream of the exhaust pipe 230a. The exhaust pipe 230a communicates with the inside of the reaction tube 212. A vacuum pump is connected to the exhaust pipe 230a via a valve 230b and a valve 230c. In addition, the exhauster 230 may be provided with a pressure detector 230d having a function of detecting the pressure in the reaction tube 212. Note that the pressure in the reaction tube 212 is regulated by the cooperation of the gas supplier and the exhauster 230. When the pressure is regulated, for example, a pressure value detected by the pressure detector 230d may be regulated to a predetermined value.

### Transfer Chamber 270

As illustrated in FIG. 2, the transfer chamber 270 is a chamber for transferring the boat 240 and the substrate S to the reactor 200. The transfer chamber 270 is a chamber to which the substrate S can also be transferred through the load-in and load-out port 144 by the transfer robot 150 in the transfer chamber 140. Although details will be described later, in the transfer chamber 270, the boat 240 on which the substrate S is supported is switched to perform transfer to the reactor 200. The transfer chamber 270 includes the plurality of boats 240, a revolution rotator 260, and a cooler 290.

The transfer chamber 270 is positioned on the lower side of the processing chamber 210 and is configured to communicate with the processing chamber 210. Specifically, the lower end of the reaction tube 212 is connected to the upper portion (ceiling portion) of the housing 272 configuring the transfer chamber 270. The transfer chamber 270 communicates with the inside of the reaction tube 212 through the furnace opening 212b.

The load-in and load-out port 144 for loading in and out the substrate S is provided on the side wall of the housing 272. The load-in and load-out port 144 is opened and closed by the gate valve 146. In the transfer chamber 270, the substrate S is placed (mounted) on the boat 240 through the load-in and load-out port 144 by the transfer robot 150, or the substrate S is taken out from the boat 240 by the transfer robot 150.

The transfer chamber 270 is provided with a boat elevator 274. The boat elevator 274 is an apparatus capable of lifting and lowering the boat 240. The boat elevator 274 includes a lid body 276 that supports the boat 240. The boat 240 is moved between the transfer chamber 270 and the processing chamber 210 as the lid body 276 is lifted and lowered. The lid body 276 is a member that closes the furnace opening 212b. An O-ring serving as a seal may be provided on the lower surface of the flange portion 212a of the reaction tube 212 or the upper surface of the lid body 276. In the case of providing the O-ring, when the boat 240 is set at a predetermined position of the processing chamber 210, the O-ring is crushed and deformed between the flange portion 212a and the lid body 276. As a result, the inside of the reaction tube 212 is kept more airtight. The lid body 276 may be provided with a heater. By providing the heater on the lid body 276, the temperature of the substrate S disposed on the lower side of the boat 240 and the temperature of the substrate S disposed on the upper side of the boat can be maintained at the same level.

A boat support 278 that supports the boat 240 is provided on the lid body 276. The boat support 278 includes a rotation shaft 278a and a rotator 278b. The rotation shaft 278a extends in the up and down direction. A bottom plate portion 244 of the boat 240 is connected to the upper end of the rotation shaft 278a. When the rotation shaft 278a is rotated in a state where the bottom plate portion 244 of the boat 240 is connected to the upper end of the rotation shaft 278a, the boat 240 is rotated with respect to the lid body 276. For example, the boat 240 accommodated in the processing chamber 210 is rotated by the rotation of the rotation shaft 278a. The rotator 278b is fixed to the lid body 276. The rotator 278b rotatably supports the rotation shaft 278a.

The boat elevator 274 moves the lid body 276 to the lower side and receives the boat 240 from a boat support 262 on the revolution rotator 260 at the upper end of the rotation shaft 278a. When receiving the boat 240, the boat elevator 274 lifts the lid body 276. Then, the boat 240 is accommodated in the processing chamber 210. In addition, the boat elevator 274 lowers the lid body 276 and takes out the boat 240 from the processing chamber 210 after the substrate processing of the substrate S in the processing chamber 210 is ended. Then, the boat 240 is transferred from the rotation shaft 278a on the lid body 276 to the boat support 262 on the revolution rotator 260.

An exhauster 280 is connected to the transfer chamber 270. The exhauster 280 is an apparatus that performs vacuum-exhaust so that the pressure in the transfer chamber 270 is a predetermined pressure (the degree of vacuum). The exhauster 280 includes an exhaust pipe 280a, a valve 280b, and an APC valve 280c. Note that a vacuum pump (not illustrated) may be included in the exhauster 280. The exhaust pipe 280a communicates with the transfer chamber 270. A vacuum pump is connected to the exhaust pipe 280a via the valve 280b and the valve 280c. The exhauster 280 may be provided with a pressure detector 280d having a function of detecting the pressure in the transfer chamber 270.

The boat 240 is a support capable of supporting the substrate S. The boat 240 is configured to be capable of supporting at least one substrate S. In the case of supporting a plurality of substrates S, the substrates S are supported at intervals in the up and down direction. The boat 240 includes a top plate portion 242, a bottom plate portion 244, and a support 246. The support 246 is positioned between the top plate portion 242 and the bottom plate portion 244. Further, the support 246 includes a plurality of mounting tables (not illustrated) on which the plurality of substrates S can be supported at intervals in the up and down direction. In other words, in the support 246, the plurality of substrates S can be supported in multiple stages in the up and down direction by the plurality of mounting tables. In the present embodiment, three boats 240 are used as an example, and a boat A is defined as a boat 240a, a boat B is defined as a boat 240b, and a boat C is defined as a boat 240c. In the present embodiment, the boat 240 may indicate any one or all of the boat 240a, the boat 240b, and the boat 240c.

As illustrated in FIG. 1, the revolution rotator 260 is an apparatus capable of causing the boat 240 to revolve. The revolution rotator 260 includes the boat support 262, a revolution table 264, a revolution shaft 266, and a revolution mechanism 268.

The boat support 262 is a portion that supports the boat 240. A plurality of boat supports 262 are provided on the revolution table 264. Specifically, the plurality of boat supports are provided at intervals in the rotation direction of the revolution table 264. In the present embodiment, as an example, three boat supports 262 are provided on the revolution table 264. The boat support 262 includes a boat support 262a corresponding to the boat 240a, a boat support 262b for the boat 240b, and a boat support 262c for the boat 240c. In addition, in the present embodiment, the boat support 262 may indicate any one or all of the boat support 262a, the boat support 262b, and the boat support 262c. The boat support 262 includes a rotation shaft 263 and a rotator 265. The rotation shaft 263 extends in the up and down direction from the revolution table 264. The upper end of the rotation shaft 263 is detachably connected to the bottom plate portion 244 of the boat 240. When the rotation shaft 263 is rotated in a state where the bottom plate portion 244 is connected to the upper end of the rotation shaft 263, the boat 240 is rotated with respect to the revolution table 264. For example, the direction of the boat 240 can be regulated by the boat 240 that is rotated when the substrate S is transferred by the transfer robot 150. The rotator 265 is fixed to the revolution table 264 and rotatably supports the rotation shaft 263.

The plurality of boat supports 262 are provided on the upper surface of the revolution table 264. The revolution shaft 266 is connected to the central portion of the revolution table 264. The revolution table 264 is rotated by the rotation of the revolution shaft 266. The rotation of the revolution table 264 causes the boat support 262 to revolve around the revolution shaft 266.

The revolution shaft 266 is connected to the revolution table 264. The revolution shaft 266 extends in the up and down direction and penetrates through the bottom wall of the transfer chamber 270. The revolution shaft 266 rotates the revolution table 264 by a rotational force from the revolution mechanism 268 to cause the boat support 262 to revolve. The revolution mechanism 268 is controlled by the controller 400.

The revolution mechanism 268 is provided on the lower surface of the bottom wall of the transfer chamber 270 and rotatably supports the revolution shaft 266. For example, the boat 240 is moved from a position adjacent to the load-in and load-out port 144 to the lower side of the processing chamber 210 by causing the revolution table 264 to revolve and move. Specifically, when the boat is moved to the next area, the revolution table 264 is rotated to cause the boat to revolve by approximately 120 degrees in accordance with the situation.

A plurality of coolers 290 are provided on the revolution table 264 in accordance with the plurality of boats 240. For example, a cooler 290a is provided in the boat 240a described later, a cooler 290b is provided in the boat 240b described later, and a cooler 290c is provided in the boat 240c described later.

As illustrated in FIG. 1, the transfer chamber 270 includes a first area A1, a second area A2, and a third area A3 in an area on the upper side of the revolution rotator 260.

The first area A1 is an area in which the boat 240 can be moved between the revolution rotator 260 and the boat elevator 274. Specifically, in the first area A1, the boat 240 is moved between the boat support 262 of the revolution rotator 260 and the boat support 278 of the boat elevator 274. The first area A1 is disposed on the lower side of the processing chamber 210.

The second area A2 is an area in which the boat 240 and the substrate S after heating processing can be made to stand by. In addition, the second area A2 is an area in which the boat 240 and the substrate S after heating processing can also be cooled. Specifically, in the second area A2, inert gas is sent from the cooler 290 toward the boat 240 and the substrate S after heating processing. As a result, the heating processed substrate S is cooled. The second area A2 is disposed downstream of the first area A1 in the rotation direction when the revolution rotator 260 is rotated clockwise.

The third area A3 is an area adjacent to the transfer chamber 140 and is capable of transferring the substrate S with respect to the transfer chamber 140. Specifically, the transfer robot 150 transfers the unprocessed substrate S with respect to the boat 240 positioned in the third area A3, or receives the processed substrate S from the boat 240 positioned in the third area A3. In this manner, the substrate S is transferred between the third area A3 and the transfer chamber 140. In the third area A3, the boat 240 is disposed at a position facing the load-in and load-out port 144, and the transfer robot 150 is capable of transferring the substrate S.

In the present embodiment, as illustrated in FIG. 1, for the sake of convenience, the first area A1, the second area A2, and the third area A3 are set as areas of equal angles (120 degrees) about the rotation axis of the revolution rotator 260. That is, the sizes of the first area A1, the second area A2, and the third area A3 are set to be the same. The present disclosure is not limited to this configuration. The size of each area may be appropriately set. Further, different areas from the first area A1, the second area A2, and the third area A3 may be newly set.

### Controller

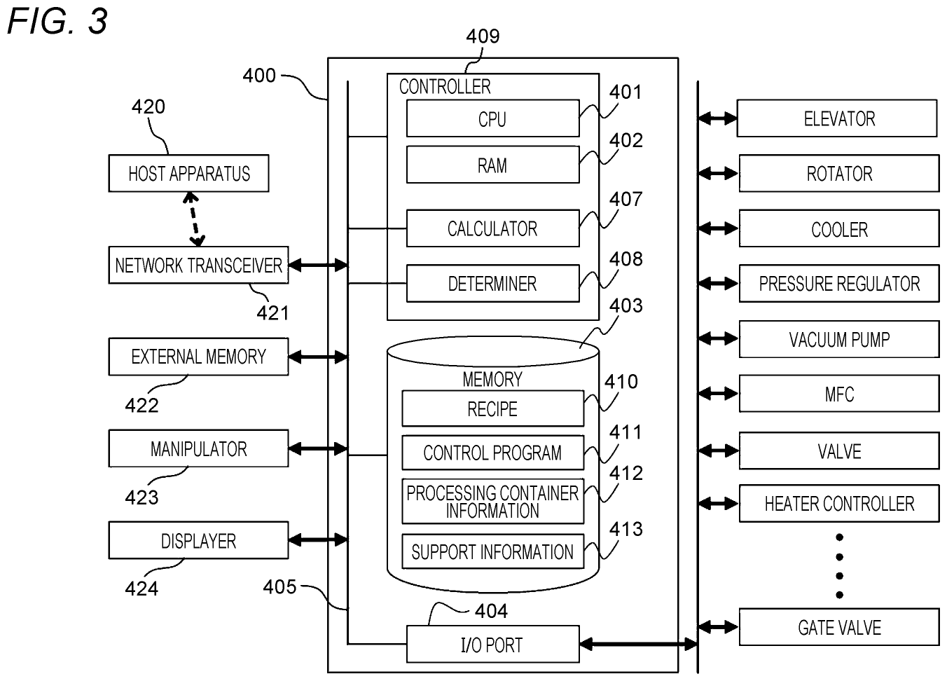

Next, the controller 400 will be described with reference to FIG. 3.

The controller 400 controls the operation of each constituent of the substrate processing apparatus 100.

The controller 400 is configured as a computer that includes a controller 409 including a central processing unit (CPU) 401 and a random access memory (RAM) 402, a memory 403 serving as a memory, and an I/O port 404. The RAM 402, the memory 403, and the I/O port 404 are configured to be capable of exchanging data with the CPU 401 via an internal bus 405.

Furthermore, as illustrated in FIG. 3, the controller 409 may include a calculator 407 that performs arithmetic in the substrate processing apparatus 100 and a determiner 408 that selects each operation in the substrate processing apparatus 100. In addition, the arithmetic in the substrate processing apparatus 100 may be performed by one of the functions of the CPU 401, and the selection of each operation in the substrate processing apparatus 100 may be performed by one of the functions of the CPU 401. That is, the calculator 407 and the determiner 408 may be configured by the function of the CPU 401.

The CPU 401 is configured to read and execute a control program from the memory 403, and to read a process recipe from the memory 403 in response to an input of an operation command from a manipulator 423 serving as an inputter/outputter or the like. Then, the CPU 401 is configured to be capable of controlling, for example, the opening/closing operation of the gate valve 146, the on/off control of each pump, the flow rate regulating operation of the MFC, the opening/closing operation of the valve, and the like, in accordance with the contents of the read process recipe. The manipulator 423 is connected to a displayer 424 such as a display capable of displaying the processing state of the substrate S via the internal bus 405. In addition, the manipulator 423 may be directly connected to the displayer 424. When the manipulator 423 is a touch panel having the function of the displayer 424, the displayer 424 may be omitted.

The memory 403 includes, for example, a flash memory, a hard disk drive (HDD), and the like. In the memory 403, a recipe 410 including a process recipe or the like in which the procedures, the conditions, and the like of the substrate processing are described, a control program 411 for controlling the operation of the substrate processing apparatus 100, a processing container information 412 in which information relevant to the reaction tube 212 is stored, a support information 413 in which information relevant to the boat 240 is stored, and the like are stored in a readable manner.

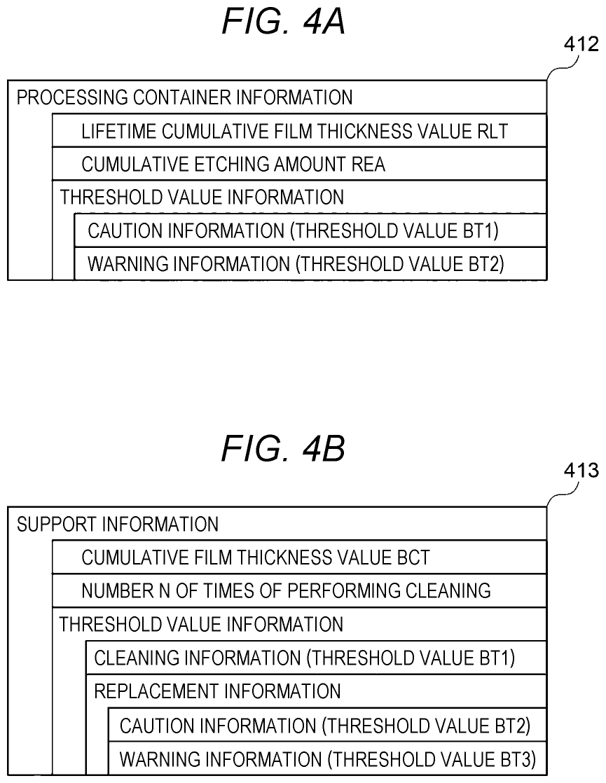

As illustrated in FIG. 4A, the processing container information 412 may include a lifetime cumulative film thickness value RLT, which is a cumulative value of the thickness of a film (an example of a deposit) adhering to the inside of the reaction tube 212 by the processing of the substrate S, and a cumulative etching amount REA estimated from cleaning processing performed to remove the film that has adhered. Here, the lifetime cumulative film thickness value RLT is a cumulative film thickness value from the start of use of the reaction tube 212, and is a value that is not subtracted in the middle while the deposit remains in the reaction tube 212. The film thickness value to adhere is obtained from the type of processing gas used for the processing of the substrate S and the time of the substrate processing. As the film thickness value, several types of patterns may be obtained by experiment and stored in the memory 403. The cumulative etching amount REA is a cumulative etching amount estimated from the cleaning processing from the start of use of the reaction tube 212, and is a value that is not subtracted in the middle. Note that the etching amount is obtained from the type of cleaning gas and the time of the cleaning processing. In addition, several types of patterns may be obtained by experiment and stored in the memory 403 as the etching amount.

In addition, the processing container information 412 may include threshold value information of the reaction tube 212. The threshold value information may include a threshold value RT1 for determining a caution state of the reaction tube 212 and a threshold value RT2 for determining a warning state of the reaction tube 212. The caution state of the reaction tube 212 is a state from the initial stage to the middle stage at the replacement time of the reaction tube 212, and indicates a state in which the reaction tube 212 for replacement is to be prepared. On the other hand, the warning state of the reaction tube 212 is a state from the middle stage to the end stage at the replacement time of the reaction tube 212, and indicates a state in which the reaction tube 212 is to be immediately replaced.

As illustrated in FIG. 4B, the support information 413 may include a cumulative film thickness value BCT, which is a cumulative value of the thickness of a film (an example of a deposit) adhering to the boat 240 by the processing of the substrate S and the number N of times of performing the cleaning processing (hereinafter, appropriately referred to as “number N of times of performing cleaning”.) performed to remove the film that has adhered. The support information 413 may include threshold value information of the boat 240. The threshold value information may include cleaning information of the boat 240 and replacement information of the boat 240. The cleaning information of the boat 240 may include a threshold value BT1 for determining a cleaning processing start timing of the boat 240. The replacement information of the boat 240 may include a threshold value BT2 for determining a caution state relevant to the replacement of the boat 240 and a threshold value BT3 for determining a warning state relevant to the replacement of the boat 240. The support information 413 is stored in the memory 403 for each boat 240.

In the present embodiment, each piece of threshold value information included in the processing container information 412 is set using the manipulator 423. Similarly, each piece of threshold value information included in the support information 413 is set using the manipulator 423. Note that the present disclosure is not limited thereto, and each piece of threshold value information may be set in advance.

Note that the process recipe functions as a program for causing the controller 400 to execute each procedure in a substrate processing step, described later, to obtain a predetermined result.

Hereinafter, for example, the process recipe, the control program, and the like will also be collectively and simply referred to as a program. Note that the term “program” in the present specification may include only the process recipe, may include only the control program, or may include both thereof. The RAM 402 is configured as a memory area (working area) in which the program, data, or the like read by the CPU 401 is temporarily stored.

The I/O port 404 is connected to each configuration such as the gate valve 146, each pressure regulator, each pump, and a heater controller. The controller 400 is provided with a network transceiver 421 that is connected to a host apparatus 420 via a network.

For example, the controller 400 according to this technology can be configured by installing a program in a computer using an external memory 422 that stores the above-described program. Note that examples of the external memory 422 include a magnetic disk such as a hard disk, an optical disk such as a DVD, a magneto-optical disk such as an MO, and a semiconductor memory such as a USB memory. For supply of the program to a computer, the supply is not limited to supply via the external memory 422. For example, the program may be supplied using a communicator such as the Internet or a dedicated line without using the external memory 422. Note that the memory 403 and the external memory 422 are configured as a computer-readable recording medium. Hereinafter, the memory and the external memory will also be collectively and simply referred to as a recording medium. Note that, herein, the term “recording medium” in the present specification may include only the memory 403, may include only the external memory 422, or may include both thereof.

The controller 409 of the controller 400 is configured to be capable of calculating a difference D between the lifetime cumulative film thickness value RLT, which is the cumulative value of the thickness of the film adhering to the inside of the reaction tube 212 by the processing of the substrate S, and the cumulative etching amount REA estimated from the cleaning processing of removing the film that has adhered, and obtaining the replacement time of the reaction tube 212 on the basis of the difference D. Specifically, as described above, the controller 409 of the present embodiment includes the CPU 401, the RAM 402, the calculator 407 that calculates the difference D, and the determiner 408 that determines the replacement time of the reaction tube 212 on the basis of the difference D.

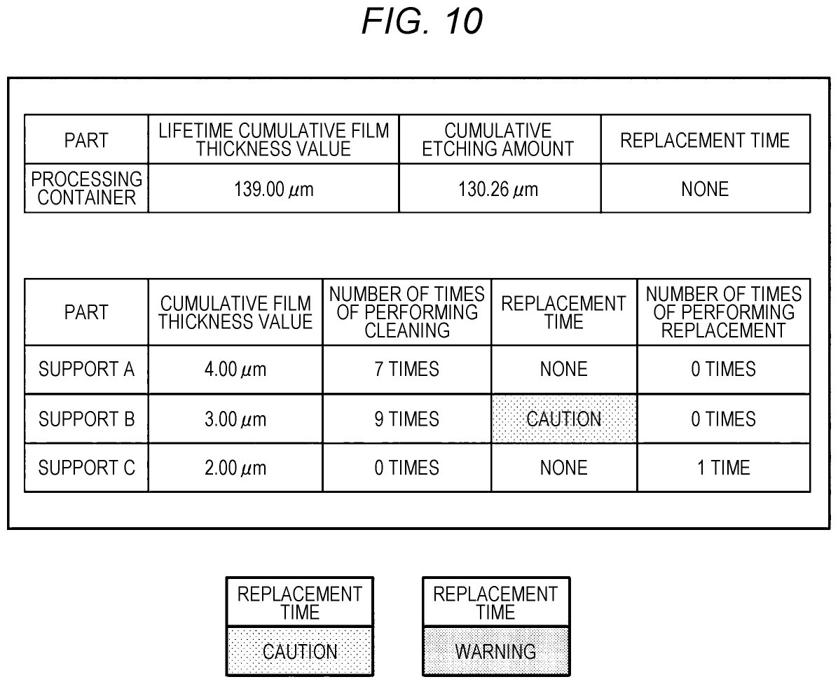

The determiner 408 determines the replacement time of the reaction tube 212 by comparing a preset threshold value with the difference D. Specifically, the determiner 408 compares the threshold value RT1 indicating the caution state at the replacement time in the reaction tube 212 with the difference D, and determines that the reaction tube 212 is at the replacement time when the difference D is the threshold value RT1 or more. Then, the controller 409 notifies a determination result by the determiner 408. Specifically, when the determiner 408 determines that the reaction tube 212 is at the replacement time, the controller 409 causes the displayer 424 capable of displaying the processing state of the substrate S to display a display indicating the replacement of the reaction tube 212 on the displayer 424 (refer to FIG. 10).

The determiner 408 compares the threshold value RT2 indicating the warning state at the replacement time in the reaction tube 212 with the difference D, and determines that the reaction tube 212 is at the time to be immediately replaced when the difference D is the threshold value RT2 or more. Then, the controller 409 notifies a determination result by the determiner 408. Specifically, when the determiner 408 determines that the reaction tube 212 is at the replacement time, the controller 409 causes the displayer 424 capable of displaying the processing state of the substrate S to display a display indicating the replacement of the reaction tube 212 on the displayer 424 (refer to FIG. 10).

In addition, the controller 409 performs control such that the display indicating the replacement of the reaction tube 212 is different before and after the difference D is greater than the threshold value. Specifically, when the difference D is the threshold value RT1 or more, the controller 409 controls the displayer 424 such that the color of the caution display indicating the replacement time of the reaction tube 212 is changed. When the difference D is the threshold value RT2 or more, the controller 409 returns the color of the caution display indicating the replacement time to the original color, and controls the displayer 424 such that the color of the warning display indicating the replacement time of the reaction tube 212 is changed (refer to FIG. 10).

In the present embodiment, as an example, the determiner 408 determines the caution state at the replacement time or the warning state at the replacement time by comparing the difference D between the lifetime cumulative film thickness value RLT and the cumulative etching amount REA with the threshold value RT1 indicating the caution state at the replacement time or the threshold value RT2 indicating the warning state at the replacement time, but the present disclosure is not limited to such a configuration. For example, the memory 403 may store a cumulative value of an over-etching amount when the reaction tube 212 is over-etched by the cleaning processing, and the determiner 408 may compare the cumulative value of the over-etching amount stored in the memory 403 with a threshold value to determine the presence or absence of the caution state at the replacement time or the warning state at the replacement time. In addition, for example, the memory 403 may store the number of times of performing the over-etching instead of the over-etching amount, and the determiner 408 may compare the number of times of performing the over-etching with a threshold value to determine the presence or absence of the caution state or the warning state at the replacement time.

In the present embodiment, as an example, the determination result by the determiner 408 is displayed on the displayer 424, but the present disclosure is not limited to such a configuration. For example, the replacement time may be notified by voice or the like while being displayed on the displayer 424. Alternatively, the notification may be made via a communication line.

In addition, the controller 400 including the controller 409 may perform control such that the cleaning processing is performed in a state where the boat 240 is loaded into the reaction tube 212. In addition, the controller 409 may perform control such that the cleaning processing is performed in a state where the boat 240 does not support the substrate S. In this case, the boat 240 and the reaction tube 212 can be simultaneously subjected to the cleaning processing. Note that the present disclosure is not limited to such a configuration, and the controller 409 may perform control such that the cleaning processing is performed in a state where the boat 240 is loaded out from the reaction tube 212. In this case, only the reaction tube 212 can be subjected to the cleaning processing.

When the reaction tube 212 is replaced, the controller 409 performs control on the memory 403 such that each of the lifetime cumulative film thickness value RLT and the cumulative etching amount REA of the reaction tube 212 is cleared (to be zero). In addition, when the reaction tube 212 is over-etched by the cleaning processing, the deposit does not remain in the reaction tube 212, and thus, the controller 409 may perform control such that each of the lifetime cumulative film thickness value RLT and the cumulative etching amount REA is cleared (to be zero).

In addition, the determiner 408 may determine the replacement time of the boat 240 on the basis of the number N of times of performing the cleaning processing on the boat 240. The determiner 408 determines the replacement time of the boat 240 by comparing a preset threshold value with the number N of times. Specifically, the determiner 408 compares the threshold value BT2 indicating the caution state at the replacement time in the boat 240 with the number N of times, and determines that the boat 204 is at the replacement time when the number N of times is the threshold value RT1 or more. Then, the controller 409 notifies a determination result by the determiner 408. Specifically, when the determiner 408 determines that the boat 240 is at the replacement time, the controller 409 causes the displayer 424 to display the display indicating the replacement of the boat 240 on the displayer 424 (refer to FIG. 10).

In addition, the determiner 408 compares the threshold value BT3 indicating the warning state at the replacement time in the boat 240 with the number N of times, and determines that the boat 240 is at the time to be immediately replaced when the number N of times is the threshold value BT3 or more. Then, the controller 409 notifies a determination result by the determiner 408. Specifically, when the determiner 408 determines that the boat 240 is at the replacement time, the controller 409 causes the displayer 424 capable of displaying the processing state of the substrate S to display the display indicating the replacement of the boat 240 on the displayer 424 (refer to FIG. 10).

In addition, when the boat 240 is replaced, the controller 409 performs control on the memory 403 such that each of the cumulative film thickness value BCT and the number N of times of performing the cleaning of the replaced boat 240 is cleared (to be zero).

### (2) Substrate Processing Step

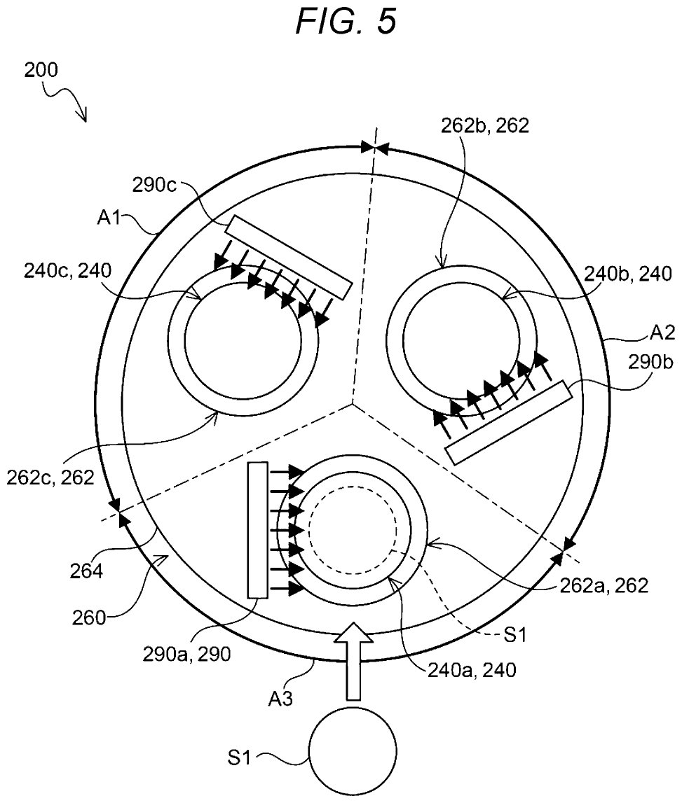

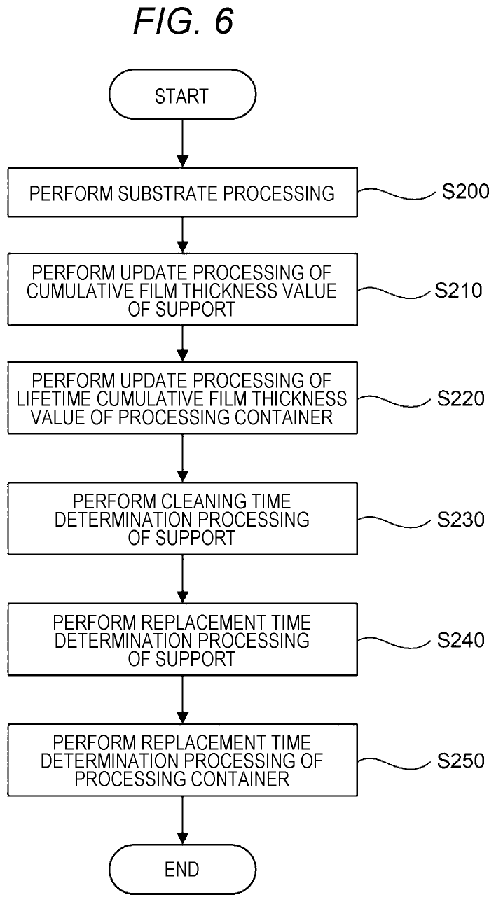

Next, the substrate processing step will be described with reference to FIGS. 5 and 6. Next, as one step of the substrate processing apparatus, a step of processing the substrate S using the substrate processing apparatus 100 having the above-described configuration will be described. Note that, in the following description, the controller 400 controls the operation of each constituent configuring the substrate processing apparatus 100.

First, as illustrated in FIG. 5, the substrate S is transferred from the transfer chamber 140 to the boat 240a in the third area A3 of the transfer chamber 270 using the transfer robot 150. Here, the substrate S to be transferred to the boat 240a is denoted by reference numeral S1 for convenience.

Next, due to the rotation of the revolution rotator 260 (clockwise rotation in FIG. 5), the boat 240a that supports the substrate S1 revolves to move from the third area A3 to the first area A1, and the boat 240b (appropriately referred to as the “empty boat 240”) that does not support the substrate revolves to move from the second area A2 to the third area A3. Here, the next substrate S (second substrate) is transferred from the transfer chamber 140 to the empty boat 240b moved to the third area A3 using the transfer robot 150.

When the boat 240a that supports the substrate S1 is moved to the first area A1, the boat 240a is lifted while being supported by the boat elevator 274. Then, the boat 240a is accommodated in the processing chamber 210. That is, the boat 240a positioned in the first area A1 is loaded into the processing chamber 210.

The boat 240a accommodated in the processing chamber 210 is subjected to heating processing. That is, the first gas and the second gas are supplied to the substrate S1 supported by the boat 240a, and a film is formed by the substrate processing including the heating processing. The substrate processing is performed on the substrate S1 in this manner (step S200 illustrated in FIG. 6).

When the heating processing of the substrate S is ended, the pressure between the processing chamber 210 and the transfer chamber 270 is regulated, and the boat 240a is taken out from the processing chamber 210 by the boat elevator 274. The boat 240a loaded out from the processing chamber 210 is delivered to the boat support 262a in the first area A1 of the revolution rotator 260.

The boat 240a loaded out from the processing chamber 210 revolves to move from the first area A1 to the second area A2 by the rotation of the revolution rotator 260. The boat 240a moved to the second area A2 is cooled by the inert gas sent from the cooler 290a. That is, the substrate S1 supported by the boat 240a is cooled by the inert gas.

Next, since the film thickness of the film adhering to the boat 240a used is increased by the substrate processing of the substrate S1, a cumulative film thickness value BCT1a of the boat 240a is updated (step S210).

In addition, since the film thickness of the film adhering to the inner surface of the reaction tube 212 is increased by the substrate processing of the substrate S1, the lifetime cumulative film thickness value RLT of the reaction tube 212 is updated (step S220). Note that the order of step S210 and step S220 may be changed.

Next, cleaning time determination processing of the boat 240 (here, the boat 240a) is performed (step S230). The cleaning time determination processing of the boat 240 will be described later.

Further, replacement time determination processing of the boat 240 (here, the boat 240a) is performed (step S240). The replacement time determination processing of the boat 240 will be described later.

Further, replacement time determination processing for the reaction tube 212 is performed (step S250). The replacement time determination processing of the reaction tube 212 will be described later. Note that the order of step S230, step S240, and step S250 may be changed.

Further, step S210, step S220, step S230, step S240, and step S250 may be executed during the substrate processing.

As described above, the substrate processing step of the substrate S1 is completed. When the substrate processing of the substrate S1 is completed, the boat 240b that supports the second substrate S is accommodated in the processing chamber 210, and the above-described step S200 to step S250 are repeated.

### (3) Cleaning Time Determination Processing Step

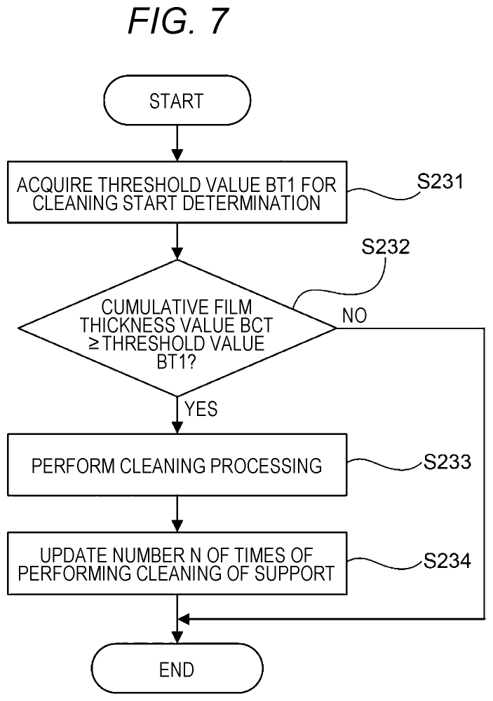

Next, a cleaning time determination processing step will be described with reference to FIG. 7. Next, as one step of the substrate processing apparatus, a step of performing the determination processing of the cleaning time for the boat 240 of the substrate processing apparatus 100 having the above-described configuration will be described. In the present embodiment, when the cleaning processing is performed, the cleaning processing is performed by accommodating the boat 240 in the reaction tube 212. Therefore, the cleaning processing is performed on the reaction tube 212 together with the boat 240. In addition, in the following description, the controller 400 controls the operation of each constituent configuring the substrate processing apparatus 100. In addition, the following description will be given using the boat A (boat 240a) as an example of the boat 240 that performs the substrate processing. The same applies to a case where the substrate processing is performed by the boat B (boat 240b) and the boat C (boat 240c), which are not described below.

First, when the substrate processing (step S200) of the substrates S1 is ended in the substrate processing step, the cumulative film thickness value BCT1a of the boat 240a used for the substrate processing is updated in step S210. Then, in step S230, the cleaning time determination processing of the boat 240a used for the substrate processing is performed. Specifically, in step S231 illustrated in FIG. 7, a threshold value BT1a for cleaning start determination is acquired.

Next, in step S232, the cumulative film thickness value BCT1a is compared with the threshold value BT1a. When the cumulative film thickness value BCT1a is the threshold value BT1a or more, it is determined that it is the cleaning time, and the processing proceeds to step S233. On the other hand, when the cumulative film thickness value BCT1a is less than the threshold value BT1a, it is determined that it is not the cleaning start time, and the processing proceeds to the next processing without performing the cleaning processing step. Note that the next processing here is the replacement time determination processing of the boat 240a (step S240).

In step S233, the cleaning processing of the boat 240a is performed. Specifically, the empty boat 240a that does not support the substrate S is loaded into the reaction tube 212 to perform the cleaning processing. Here, when it is determined that the boat 240a immediately after the substrate processing is a cleaning processing target, all the substrates S are discharged from the boat 240a before the next substrate processing is performed in the reaction tube 212, and the boat 240a is emptied and then loaded into the processing chamber 210. Then, in accordance with a predetermined procedure, the cleaning processing is performed on the boat 240a and the reaction tube 212 using the cleaning gas. When the cleaning processing is ended, the processing proceeds to step S234.

In step S234, the number N of times of performing the cleaning on the boat (hereinafter, appropriately referred to as the “cleaned boat”) 240a that has been subjected to the cleaning processing is updated. In addition, the cumulative film thickness value BCT1a of the cleaned boat 240a is cleared (to be zero). After step S234 is ended, the processing proceeds to the next processing. Note that the next processing here is the replacement time determination processing of the boat 240a (step S240).

### (4) Support Replacement Time Determination Processing Step

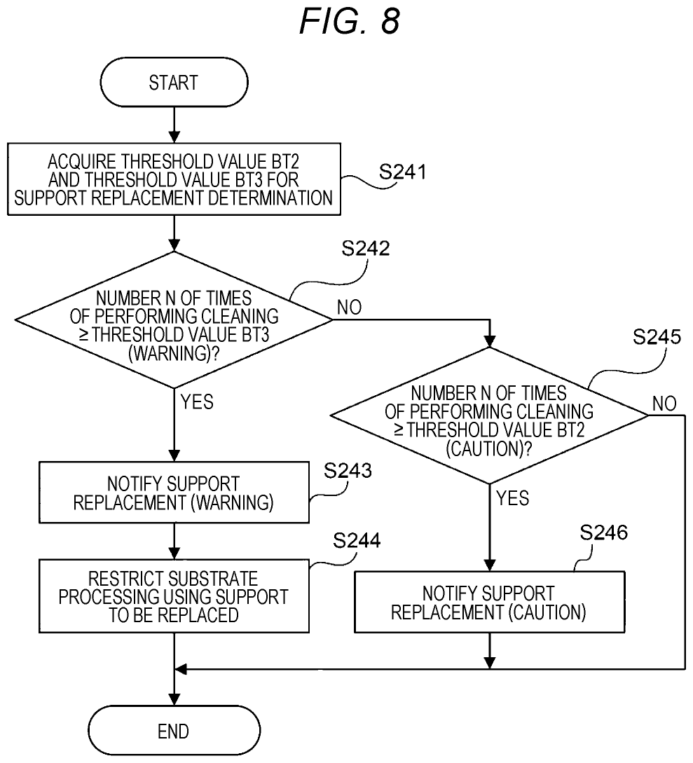

Next, a support replacement time determination processing step will be described with reference to FIG. 8. Next, as one step of the substrate processing apparatus, a step of performing the determination processing of the replacement time for the boat 240 of the substrate processing apparatus 100 having the above-described configuration will be described. In addition, in the following description, the controller 400 controls the operation of each constituent configuring the substrate processing apparatus 100. In addition, the following description will be given using the boat A (boat 240a) as an example of the boat 240 that performs the substrate processing. The same applies to a case where the substrate processing is performed by the boat B (boat 240b) and the boat C (boat 240c), which are not described below.

When the cleaning time determination processing (step S230) of the boat 240a is ended in the substrate processing step, the support replacement time determination processing is executed as step S240. First, in step S241 illustrated in FIG. 8, a threshold value BT2a for support replacement determination is acquired.

Next, in step S242, the number N of times of performing the cleaning on the boat 240a is compared with the threshold value BT2a. When the number N of times of performing the cleaning is the threshold value BT2a or more, it is determined that the boat 240a is at the time to be immediately replaced, and the processing proceeds to step S243. On the other hand, when the number N of times of performing the cleaning is less than the threshold value BT2a, the processing proceeds to step S245.

Next, in step S243, a warning is issued to immediately replace the boat 240a. Specifically, a display for prompting the replacement of the boat 240a is displayed on the displayer 424.

Next, in step S244, the substrate processing using the boat 240a to be replaced is restricted. The restriction of the substrate processing is continued until the boat 240a is replaced. After step S244 is ended, the processing proceeds to the next processing. Note that the next processing here is the replacement time determination processing of the reaction tube 212 (step S250).

Next, in step S245, the number N of times of performing the cleaning on the boat 240a is compared with a threshold value BT3a. When the number N of times of performing the cleaning is the threshold value BT3a or more, it is determined that the boat 240a is at the time to be replaced, and the processing proceeds to step S246. On the other hand, when the number N of times of performing the cleaning is less than the threshold value BT3a, it is determined that the boat 240a is not at the replacement time, and the support replacement time determination processing is ended.

Next, in step S246, a caution is issued to replace the boat 240a. Specifically, a display for prompting the replacement of the boat 240a is displayed on the displayer 424. After step S246 is ended, the processing proceeds to the next processing. Note that the next processing here is the replacement time determination processing of the reaction tube 212 (step S250).

### (5) Processing Container Replacement Time Determination Processing Step

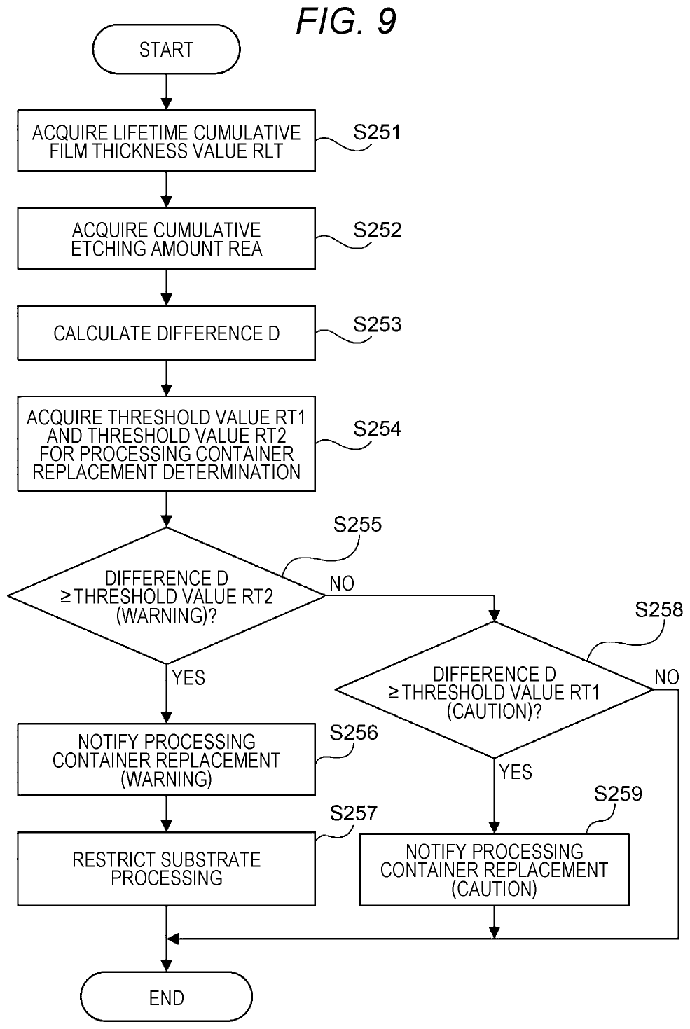

Next, a processing container replacement time determination processing step will be described with reference to FIG. 9. Next, as one step of the substrate processing apparatus, a step of performing the determination processing of the replacement time for the reaction tube 212 of the substrate processing apparatus 100 having the above-described configuration will be described. In addition, in the following description, the controller 400 controls the operation of each constituent configuring the substrate processing apparatus 100.

When the replacement time determination processing (step S240) of the boat 240a is ended in the substrate processing step, the processing container replacement time determination processing is executed in step S250. First, in step S251 illustrated in FIG. 9, the lifetime cumulative film thickness value RLT of the reaction tube 212 is acquired.

Next, in step S252, the cumulative etching amount REA is acquired. Note that step S251 and step S252 may be switched.

Next, in step S253, the difference D between the lifetime cumulative film thickness value RLT and the cumulative etching amount REA is calculated. Specifically, a value obtained by subtracting the cumulative etching amount REA from the lifetime cumulative film thickness value RLT is calculated by the calculator 407.

Next, in step S254, the threshold value RT1 and the threshold value RT2 for processing container replacement determination are acquired.

Next, in step S255, the difference D is compared with the threshold value RT1. When the difference D is the threshold value RT1 or more, it is determined that the reaction tube 212 is at the time to be immediately replaced, and the processing proceeds to step S256. On the other hand, when the difference D is less than the threshold value RT1, the processing proceeds to step S258.

Next, in step S256, a warning is issued to immediately replace the reaction tube 212. Specifically, a display for prompting the replacement of the reaction tube 212 is displayed on the displayer 424.

Next, in step S257, the use of the reaction tube 212 is restricted. The restriction of the reaction tube 212 is continued until the reaction tube 212 is replaced. When step S257 is ended, the replacement time determination processing of the reaction tube 212 is ended.

Next, in step S258, the difference D is compared with the threshold value RT2. When the difference D is the threshold value RT2 or more, it is determined that the reaction tube 212 is at the time to be replaced, and the processing proceeds to step S259. On the other hand, when the difference D is less than the threshold value RT2, the replacement time determination processing of the reaction tube 212 is ended.

Next, in step S259, a caution is issued to replace the reaction tube 212. Specifically, a display for prompting the replacement of the boat 240a is displayed on the displayer 424. When step S259 is ended, the replacement time determination processing of the reaction tube 212 is ended.

Next, function effects of this embodiment will be described.

In the present embodiment, the difference D between the lifetime cumulative film thickness value RLT and the cumulative etching amount REA is calculated by the controller 409, and the replacement time of the reaction tube 212 serving as the processing container can be obtained on the basis of the difference D. As a result, according to the present embodiment, for example, it is possible to accurately grasp the replacement time of the reaction tube 212 by a comparison with a case where the replacement time of the reaction tube 212 is obtained on the basis of the number of times of use set in advance in the reaction tube 212. By accurately grasping the replacement time of the reaction tube 212 in this manner, for example, the replacement time of the reaction tube 212 can be delayed to lengthen the period of use of the reaction tube 212.

In the present embodiment, since the controller 409 includes the calculator 407 and the determiner 408, for example, the configuration of the controller 409 can be simplified, compared with a case where the calculator 407 and the determiner 408 are provided separately.

In the present embodiment, the determiner 408 may compare the preset threshold value RT1 or threshold value RT2 with the difference D to determine the replacement time of the reaction tube 212, and the controller 409 may notify the determination result by the determiner 408. When the threshold value is set by the determiner 408 in order to obtain the replacement time of the reaction tube 212 in this manner, the replacement time of the reaction tube 212 can be grasped more accurately. In addition, since the determination result by the determiner 408 is notified, it is easy to grasp the replacement time.

In the present embodiment, it may be notified as a caution that the threshold value RT1 indicates the caution state at the replacement time in the reaction tube 212, that is, it is the initial stage of the replacement time of the reaction tube 212. In this case, it is possible to prepare the reaction tube 212 for replacement in advance.

In the present embodiment, a warning to the effect that the threshold value RT2 indicates the warning state at the replacement time in the reaction tube 212, that is, it is the middle stage of the replacement time of the reaction tube 212 may be notified. In this case, it is possible to immediately replace the processing container prepared in the caution state, which contributes to a reduction in time to wait for a processing container for replacement.

In the present embodiment, the controller 409 may perform control such that the boat 240 is loaded into the reaction tube 212 in the state of supporting the substrate S and the substrate S is processed. In this case, the plurality of substrates S can be processed simultaneously.

In the present embodiment, the determiner 408 may determine the replacement time of the boat 240 on the basis of the number N of times of performing the cleaning processing on the boat 240, and the controller 409 may notify the determination result by the determiner 408. In this case, since the number N of times of performing the cleaning is used to obtain the replacement time of the boat 240, the execution of the substrate processing using the boat 240 that is not capable of withstanding the substrate processing is restricted, and it is possible to suppress the occurrence of a defective substrate due to the breakage of the boat 240.

In the present embodiment, when the determiner 408 determines that the reaction tube 212 is at the replacement time, the controller 409 may perform control such that a display indicating the replacement of the reaction tube 212 is displayed on the displayer 424. In this case, the displayer 424 displays that it is the replacement time of the reaction tube 212, and thus, the operator can recognize that it is the replacement time of the reaction tube 212, and the operator can prepare for the replacement of the next reaction tube 212.

In the present embodiment, each threshold value may be settable using the manipulator 423. In this case, it is possible to set the threshold value according to each condition by the manipulator 423, and it is possible to extend the available period of the reaction tube 212.

In the present embodiment, at least the lifetime cumulative film thickness value RLT and the cumulative etching amount REA may be stored in the memory 403. In this case, since information for grasping the replacement time of the reaction tube 212 is stored in the memory 403, even when the substrate processing apparatus 100 is restarted, various types of information are stored, and work can be performed without collecting various types of information.

In the present embodiment, the controller 409 may control the display of the replacement time of the reaction tube 212 displayed on the displayer 424 such that the display is different before and after the difference D is greater than the threshold value BT1 and the threshold value BT2. In this case, the operator can accurately grasp the preparation and the replacement time of the reaction tube 212 by switching the display of the caution and the warning displayed on the displayer 424, and thus, it is possible to efficiently perform the preparation and the replacement work of the reaction tube 212.

In the present embodiment, the controller 409 may perform control such that the cleaning processing is performed in a state where the boat 240 is loaded into the reaction tube 212. In this case, since the reaction tube 212 and the boat 240 are simultaneously cleaned, it is easy to manage the etching amount with respect to the film adhering to the reaction tube 212 and the boat 240.

In the present embodiment, the controller 409 may perform control such that the cleaning processing is performed in a state where the boat 240 does not support the substrate S. In this case, for example, it is possible to avoid the influence on the processed substrate S, compared with a case where the cleaning processing is performed in a state where the boat 240 supports the substrates S.

In the present embodiment, the controller 409 may perform control such that the cleaning processing is performed in a state where the boat 240 is loaded out from the reaction tube 212. In this case, for example, it is possible to etch only the reaction tube 212 while avoiding the influence on the boat 240, compared with a case where the cleaning processing is performed in a state where the boat 240 is loaded into the reaction tube 212.

In the present embodiment, when the reaction tube 212 is replaced, the controller 409 may control the memory 403 such that each of the lifetime cumulative film thickness value RLT and the cumulative etching amount REA of the reaction tube 212 is cleared (to be zero) in the memory 403. In this case, by clearing the information on the reaction tube 212 before replacement stored in the memory 403, it is possible to correctly set the information on the reaction tube 212 after replacement. In addition, when the reaction tube 212 is over-etched by the cleaning processing, the memory 403 may be controlled by the controller 409 such that each of the lifetime cumulative film thickness value RLT and the cumulative etching amount REA is cleared (to be zero). The reaction tube 212 being over-etched indicates that the deposit adhering to the reaction tube 212 has disappeared, which is equivalent to a case where the reaction tube 212 is replaced. Therefore, when the reaction tube 212 is over-etched, each of the lifetime cumulative film thickness value RLT and the cumulative etching amount REA is cleared, and thus, it is possible to correctly set the information on the reaction tube 212 after the over-etching.

In the present embodiment, the memory 403 may be controlled by the controller 409 such that each of the cumulative film thickness value BCT and the number N of times of performing the cleaning of the boat 240 is cleared in the memory 403 when the boat 240 is replaced. In this case, it is possible to correctly set the information on the boat 240 after the replacement by clearing the information on the boat 240 before the replacement stored in the memory 403.

### Other Embodiments

In the above-described embodiment, the apparatus is operated by placing the substrate S on all the three boats 240, but the present disclosure is not limited to such a configuration. The apparatus may be operated by placing the substrate S on two boats 240, or the apparatus may be operated by placing the substrate S on one boat 240, among the three boats 240.

In addition, an example has been described in which a set of the reactor 200 and the transfer chamber 270 is used as the substrate processing apparatus 100, but the present disclosure is not limited thereto. For example, a plurality of sets of the reactor 200 and the transfer chamber 270 may be connected to the transfer chamber 140. In addition, a plurality of reactors 200 may be provided in the upper portion of the transfer chamber 270. In this case, the substrate processing of the substrate S can be performed by the plurality of reactors 200 in parallel. Further, each of the plurality of reactors 200 may be a chamber in which different substrate processing is performed. In this case, after the substrate processing is performed in the first reactor 200, another substrate processing may be performed in the next reactor 200.

In addition, in the substrate processing apparatus 100, the boat 240 to be used may be selectively used in accordance with the type of film to be formed on the substrate S. That is, in the boat 240 having a high usage rate, the cleaning processing is frequently performed since the film that has adhered progresses quickly. On the other hand, in the boat 240 having a low usage rate, since the progress of the film is slow, the cleaning processing may not be frequently performed.

In the above-described embodiment, an example has been described in which a film is formed by using a batch-type substrate processing apparatus that processes a plurality of substrates at a time, but the present disclosure is not limited to the above-described embodiment. For example, the present disclosure can also be suitably applied to a case where a film is formed using a single-wafer-processing-type substrate processing apparatus that processes one or a plurality of substrates at a time. In addition, in the above-described embodiment, an example has been described in which a thin film is formed using the substrate processing apparatus including a hot-wall-type processing furnace, but the present disclosure is not limited to the above-described embodiment, and can also be suitably applied to a case where a thin film is formed using a substrate processing apparatus including a cold-wall-type processing furnace.

Even in cases where such substrate processing apparatuses are used, each processing can be performed in accordance with processing procedures and processing conditions similar to those in the above-described embodiment and modified example, so that effects similar to those in the above-described embodiment and modified example can be obtained.

According to the present disclosure, it is possible to accurately grasp the replacement time of the processing container.

What is claimed is:

1. A substrate processing apparatus, comprising:
a processing container that processes a substrate;
a gas supplier configured to supply a processing gas depositing a deposit, and a cleaning gas removing the deposit into the processing chamber; and
a controller,
wherein the controller is configured to be capable of controlling the gas supplier so as to perform, a predetermined number of times, processing including:
(a) forming the deposit on the substrate and the inner side of the processing container; and
(b) removing the deposit on the inner side of the processing container, and
the controller is configured to be capable of calculating a difference between a lifetime cumulative film thickness value, which is a cumulative value of a thickness of the deposit adhering to the inner side of the processing container in (a), and a cumulative etching amount, which is an amount of a thickness of the deposit estimated to be removed in (b), and
obtaining a replacement time of the processing container on the basis of the difference.

2. The apparatus according to claim 1,
wherein the controller includes:
a calculator that calculates the difference; and
a determiner that determines the replacement time of the processing container on the basis of the difference.

3. The apparatus according to claim 2,
wherein the determiner determines the replacement time of the processing container by comparing a preset threshold value with the difference, and
the controller notifies a determination result by the determiner.

4. The apparatus according to claim 3,
wherein the threshold value indicates a caution state at the replacement time in the processing container.

5. The apparatus according to claim 3,
wherein the threshold value indicates a warning state at the replacement time in the processing container.

6. The apparatus according to claim 2, further comprising
a support that supports the substrate,
a boat elevator that carries the support into the processing container,
wherein the controller is further capable of controlling the boat elevator such that the substrate is loaded into the processing container in a state in which the substrate is supported by the support and the substrate is processed.

7. The apparatus according to claim 6,
wherein the determiner determines a replacement time of the support on the basis of the number of times of performing the cleaning processing on the support, and
the controller notifies a determination result by the determiner.

8. The apparatus according to claim 3, further comprising
a displayer that displays a processing state of the substrate,
wherein the controller is capable of performing control such that a display indicating replacement of the processing container is displayed on the displayer when the determiner determines that the processing container is at the replacement time.

9. The apparatus according to claim 3, further comprising
a manipulator that sets the threshold value.

10. The apparatus according to claim 3, further comprising
a memory that stores at least the lifetime cumulative film thickness value and the cumulative etching amount.

11. The apparatus according to claim 8,
wherein the controller is capable of performing control such that the display indicating the replacement of the processing container is different before and after the difference is greater than the threshold value.

12. The apparatus according to claim 6,
wherein the controller is capable of performing control such that the cleaning processing is performed in a state in which the support is loaded into the processing container.

13. The apparatus according to claim 12,
wherein the controller is capable of performing control such that the cleaning processing is performed in a state in which the support does not support the substrate.

14. The apparatus according to claim 6,
wherein the controller is capable of performing control such that the cleaning processing is performed in a state in which the support is loaded out from the processing container.

15. The apparatus according to claim 3, further comprising
a memory that stores at least the lifetime cumulative film thickness value and the cumulative etching amount,
wherein the controller is capable of performing control on the memory such that each of the lifetime cumulative film thickness value and the cumulative etching amount of the processing container is cleared.

16. The apparatus according to claim 15, wherein when the processing container is replaced, or when the difference obtained by subtracting the cumulative etching amount from the lifetime cumulative film thickness value is negative, the controller is capable of performing control on the memory such that each of the lifetime cumulative film thickness value and the cumulative etching amount is cleared.

17. The apparatus according to claim 3, wherein the determiner determines the replacement time of the processing container on the basis of a value obtained by accumulating a difference value when the difference obtained by subtracting the cumulative etching amount from the lifetime cumulative film thickness value is negative.

18. The apparatus according to claim 6, further comprising
a memory that stores at least the cumulative film thickness value of the deposit of the support and the number of times of performing the cleaning processing on the support,
wherein the controller is capable of performing control on the memory such that each of the cumulative film thickness value of the support and the number of times of performing the cleaning processing is cleared when the support is replaced.

19. A method of manufacturing a semiconductor device, comprising:
loading a substrate into a processing container and processing the substrate;
(c) performing, a predetermined number of times, processing including:
(a) supplying a processing gas depositing a deposit on the substrate and the inner side of the processing container; and
(b) supplying a cleaning gas removing the deposit on the inner side of the processing container; and
calculating a difference between a lifetime cumulative film thickness value, which is a cumulative value of a thickness of the deposit adhering to the inner side of the processing container in (a), and a cumulative etching amount, which is an amount of a thickness of the deposit estimated to be removed in (b), and obtaining a replacement time of the processing container on the basis of the difference.

20. A non-transitory computer-readable recording medium storing a program that causes, by a computer, a substrate processing apparatus to perform a process comprising:
loading a substrate into a processing container and processing the substrate;
(c) performing, a predetermined number of times, processing including:
(a) supplying a processing gas depositing a deposit on the substrate and the inner side of the processing container; and
(b) supplying a cleaning gas removing the deposit on the inner side of the processing container; and
calculating a difference between a lifetime cumulative film thickness value, which is a cumulative value of a thickness of the deposit adhering to the inner side of the processing container in (a), and a cumulative etching amount, which is an amount of a thickness of the deposit estimated to be removed in (b), and obtaining a replacement time of the processing container on the basis of the difference.
